(19) United States
(12) Patent Application Publication
(10) Pub. No.: US 2016/0372530 A1
(43) Pub. Date: Dec. 22, 2016

(54) ORGANIC LIGHT EMITTING DISPLAY AND MANUFACTURING METHOD FOR THE SAME

(71) Applicant: Samsung Display Co., Ltd., Yongin-si (KR)

(72) Inventors: Jin Taek KIM, Yongin-si (KR); Tae Woong KIM, Yongin-si (KR); Bo Ik PARK, Yongin-si (KR); Young Gug SEOL, Yongin-si (KR); Sun Hee LEE, Yongin-si (KR); Pil Suk LEE, Yongin-si (KR)

(21) Appl. No.: 15/017,430

(22) Filed: Feb. 5, 2016

(30) Foreign Application Priority Data
Jun. 16, 2015 (KR) 10-2015-0085452

(51) Int. Cl. H01L 27/32; H01L 51/56; H01L 51/50; H01L 51/00

(52) U.S. Cl. CPC H01L 27/3258; H01L 51/0035; H01L 51/004; H01L 27/3262; H01L 51/0018; H01L 51/56; H01L 51/5012; H01L 27/1248

(57) ABSTRACT

An organic light emitting diode (OLED) display comprises a substrate, a semiconductor layer portion disposed over the substrate and comprising an active region, a source region, and a drain region, a first insulation layer disposed over the substrate, a gate electrode disposed over the first insulation layer and overlapping the active region, and a second insulation layer disposed over the first insulation layer. First and second insulation material pieces are disposed over the second insulation layer. Source and drain electrodes are disposed over the first and second insulation material pieces and connected the source and drain regions through contact vias formed through the first and second insulation material pieces, respectively. A third insulation layer is disposed over the second insulation layer and covering the source electrode and the drain electrode. The display further includes a first electrode connected to the drain electrode, an organic light emission layer and a second electrode.

### CROSS-REFERENCE TO RELATED APPLICATION

This application claims priority to and the benefit of Korean Patent Application No. 10-2015-0085452, filed on Jun. 16, 2015, in the Korean Intellectual Property Office, the entire contents of which are incorporated herein by reference in their entirety.

### BACKGROUND

(a) Field

The present disclosure relates to an organic light emitting diode (OLED) display and the manufacturing method thereof.

(b) Discussion of the Related Technology

An organic light emitting diode (OLED) display is a display device using an organic light emitting element, is more resistant to impact or vibration that other display device, has a wide viewing angle, and is able to provide clear motion picture through fast response speed.

However, an organic light emitting diode (OLED) display has characteristic that is degraded by an outside oxygen and moisture invasion. So as to resolve the problem, a sealing structure is being applied to protect the organic light emitting element from the outside oxygen and the moisture.

Recently, an organic light emitting diode (OLED) display is being applied to a flexible display device that can be bent or folded to meet the needs of the user, and the application and the use thereof is being expanded.

The above information disclosed in this Background section is only for enhancement of understanding of the background of the invention and therefore it may contain information that does not form the prior art that is already known in this country to a person of ordinary skill in the art.

### SUMMARY

An aspect of the present invention provides an organic light emitting diode (OLED) display having advantages of a flexible characteristic and the manufacturing method thereof.

Also, another aspect of the present invention provides an organic light emitting diode (OLED) display that minimizes organic insulation material piece in a pixel area to minimize the degradation that is caused by an out-gassing phenomenon and the manufacturing method thereof.

Still another aspect of the invention provides an organic light emitting diode (OLED) display device, which may comprise: a substrate; a semiconductor layer portion disposed over the substrate and comprising an active region, a source region, and a drain region; a first insulation layer disposed over the substrate and covering the semiconductor layer portion; a gate electrode disposed over the first insulation layer and overlapping the active region, the first insulation layer interposed between the gate electrode and the semiconductor layer portion; a second insulation layer disposed over the first insulation layer and covering the gate electrode; a first insulation material piece disposed over the second insulation layer; a source electrode disposed over the first insulation material piece and connected the source region through a contact via formed through the first and second insulation layers and the first insulation material piece; a second insulation material piece disposed over the second insulation layer; a drain electrode disposed over the second insulation material piece and connected to the drain region through another contact via formed through the first and second insulation layers and the second insulation material piece; a third insulation layer disposed over the second insulation layer and covering the source electrode and the drain electrode; a first electrode disposed over the third insulation layer and connected to the drain electrode through a contact hole formed through the third insulation layer; an organic light emission layer disposed over the first electrode; and a second electrode disposed over the organic light emission layer.

In the foregoing device, the first insulation material piece may be disposed between the source electrode and the second insulation layer. When viewed in a viewing direction perpendicular to a major surface of the substrate, the first insulation material piece and the source electrode may eclipse with each other such that the first insulation material piece does not comprises a substantial portion that does not overlap the source electrode. The second insulation material piece may be disposed between the drain electrode and the second insulation layer, wherein, when viewed in a viewing direction perpendicular to a major surface of the substrate, the second insulation material piece and the drain electrode eclipse with each other such that the second insulation material piece does not comprises a substantial portion that does not overlap the drain electrode.

Still in the foregoing device, the first insulation material piece may be formed of an organic insulation material that comprises photosensitive and thermosetting material. The organic insulation material may comprise at least one selected from acryl-based polymer, imide-based polymer, aryl-ether based polymer, amide based polymer and siloxane. A weight-loss of the organic insulating material may be smaller than about 0.5% at a temperature below about 400° C. The third insulation layer may comprise polyimide. The organic light emitting diode display device may comprise an array of pixels, each of which comprises the semiconductor layer portion, the first insulation layer, the gate electrode, the second insulation layer, the first insulation material piece, the source electrode, the second insulation material piece, the drain electrode, the third insulation layer, the first electrode, the organic light emitting layer and the second electrode.

A further aspect of the invention provides a method of manufacturing an organic light emitting diode (OLED) display, which may comprise: forming a semiconductor layer portion comprising an active region, a source region, and a drain region over a substrate; forming a first insulation layer over the semiconductor layer portion; forming a gate electrode over the first insulation layer and overlapping the active region; forming a second insulation layer over the gate electrode; forming an extra insulation layer over the second insulation layer; forming a source electrode and a drain electrode over the extra insulation layer, wherein the source electrode is connected to the source region via a contact hole formed through the first and second insulation layers and the extra insulation layer, wherein the drain electrode is connected to the drain region via a contact hole formed through the first and second insulation layers and the extra insulation layer; etching at least a portion of the extra insulation layer that is exposed outside the source and drain electrodes by using the source electrode and the drain electrode as an etching mask, thereby forming first and second insulation material pieces; forming a third insulation layer over the source electrode and the drain electrode; forming a first electrode over the third insulation layer, wherein the first electrode is connected to the drain electrode through a contact hole; forming an organic emission layer over the first electrode; and forming a second electrode over the organic emission layer.

In the foregoing method, etching may comprise irradiating ultraviolet (UV) light. The first insulation material piece may be disposed between the source electrode and the second insulation layer, and the second insulation material piece may be disposed between the drain electrode and the second insulation layer. When viewed in a viewing direction perpendicular to a major surface of the substrate, the first insulation material piece and the source electrode may eclipse with each other such that the first insulation material piece does not comprises a substantial portion that does not overlap the source electrode. When viewed in a viewing direction perpendicular to a major surface of the substrate, the second insulation material piece and the drain electrode may eclipse with each other such that the second insulation material piece does not comprises a substantial portion that does not overlap the source electrode.

Still in the foregoing method, the first and second insulation material pieces may comprise organic insulating material that comprises photosensitive and thermosetting material. The organic insulating material may comprise at least one that is selected from acryl-based polymer, imide-based polymer, aryl-ether based polymer, amide-based polymer, and siloxane. A weight-loss of the organic insulating material may be smaller than about 0.5% at a temperature below about 400° C. The third insulation layer may comprise polyimide. The method may further comprise forming at least one electrically conductive material line over the extra insulation layer; and etching at least a portion of the extra insulation layer that is exposed outside the at least one electrically conductive material line by using the at least one electrically conductive material line as an etching mask, thereby forming at least one additional insulation material piece between the at least one electrically conductive material line and the second insulation layer. The organic light emitting diode display may comprise an array of pixels, each of which comprises the semiconductor layer portion, the first insulation layer, the gate electrode, the second insulation layer, the first insulation material piece, the source electrode, the second insulation material piece, the drain electrode, the third insulation layer, the first electrode, the organic light emitting layer and the second electrode.

An organic light emitting diode (OLED) display according to an embodiment of the present invention may include a semiconductor pattern that is disposed in a substrate and includes an active region, a source region, and a drain region, a first insulation layer that is disposed on the semiconductor pattern, a gate electrode that is disposed on the first insulation layer and is overlapped with the active region, a second insulation layer that is disposed on the gate electrode, an insulation pattern that is disposed on the second insulation layer and includes at least one opening, a source electrode and a drain electrode that is disposed on the insulation pattern and respectively contacts the source region and the drain region through the opening, a third insulation layer that is disposed on the source electrode and the drain electrode, a first electrode that is disposed on the third insulation layer and is connected to the drain electrode through a contact hole, an organic emission layer that is disposed on the first electrode, and a second electrode that is disposed on the organic emission layer.

The insulation pattern may be respectively disposed at a lower portion of the source electrode and the drain electrode.

A plane view shape of the insulation pattern that is disposed at the lower portion of the source electrode and the source electrode may coincide with each other.

A plane view shape of the insulation pattern that is disposed at the lower portion of the drain electrode and the drain electrode may coincide with each other.

The insulation pattern may be organic insulation material that includes photosensitive and thermosetting material.

A weight-loss of the organic insulating material may be within 0.5% below 400° C.

The third insulation layer may include polyimide.

A manufacturing method of an organic light emitting diode (OLED) display according to an embodiment of the present invention may include forming a semiconductor pattern that includes an active region, a source region, and a drain region on a substrate, forming a first insulation layer on the semiconductor pattern, forming a gate electrode that is disposed on the first insulation layer and is overlapped with the active region, forming a second insulation layer on the gate electrode, forming an insulation pattern that includes at least one opening on the second insulation layer, forming a source electrode and a drain electrode that contacts the drain region through the opening on the insulation pattern, etching the insulation pattern that is exposed to an outside by using the source electrode and the drain electrode as an etching mask, forming a third insulation layer on the source electrode and the drain electrode, forming a first electrode that is disposed on the third insulation layer and is connected to the drain electrode through a contact hole, forming an organic emission layer on the first electrode, and forming a second electrode on the organic emission layer.

The insulation pattern etching step may include a method of irradiating ultraviolet (UV) light.

The insulation pattern is respectively disposed at a lower portion of the source electrode and the drain electrode each.

A plane view shape of the insulation pattern that is disposed at the lower portion of the source electrode and the source electrode coincides with each other.

A plane view shape of the insulation pattern that is disposed at the lower portion of the drain electrode and the drain electrode coincides with each other.

The insulation pattern may include organic insulating material that includes photosensitive and thermosetting material.

The organic insulating material may include at least one that is selected from acryl-based polymer, imide-based polymer, aryl-ether based polymer, amide-based polymer, siloxane, and so on.

A weight-loss of the organic insulating material is within 0.5% below 400° C.

The third insulation layer includes polyimide.

In accordance with an embodiment of the present invention as described above, a data wire is used as an etching mask to form organic insulation pattern in only the specific area so that the area that the organic insulation pattern occupies the display area can be reduced.

As a result, the out-gassing of the organic insulation pattern is minimized to be able to prevent the degradation of the display element.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art. In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic top plan view of an organic light emitting (OLED) display according to an embodiment of the present invention.

FIG. 2A is a top plan view that enlarges P1 of FIG. 1, and FIG. 2B is a cross-sectional view along II-IF line of FIG. 2A.

FIG. 3 is a circuit diagram of one pixel in an organic light emitting diode (OLED) display according to an embodiment of the present invention.

FIG. 4 is a cross-sectional view along I-I′ line of FIG. 1.

FIG. 5 to FIG. 15 are cross-sectional views showing a manufacturing method of an organic light emitting diode (OLED) display along an embodiment of the present invention.

### DETAILED DESCRIPTION OF EMBODIMENTS

Embodiments are described hereinbelow.

The advantages and characteristics of aspects of the present invention will become apparent from reference to embodiments in the following detailed description accompanying the drawings. However, the present invention is not limited by the hereafter-disclosed embodiments, and may be modified in various different ways. The present embodiments provide disclosure of the present invention and information of the scope of the present invention to those skilled in the art, and the present invention is defined by the scope of the claims. Like reference numerals designate like elements throughout the specification.

In addition, the size and thickness of each configuration shown in the drawings are arbitrarily shown for better understanding and ease of description, but the present invention is not limited thereto.

In the drawings, the thickness of layers, films, panels, regions, etc., are exaggerated for clarity. In the drawings, for better understanding and ease of description, the thicknesses of some layers and areas are exaggerated. It will be understood that when an element such as a layer, film, region, or substrate is referred to as being “on” another element, it can be directly on the other element or intervening elements may also be present.

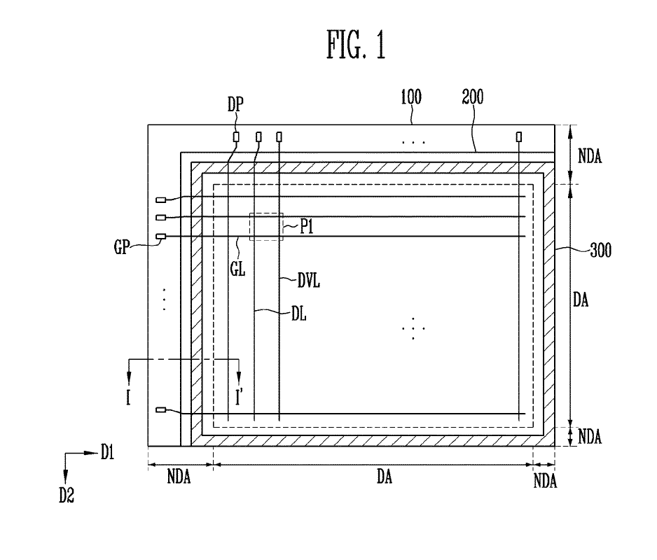

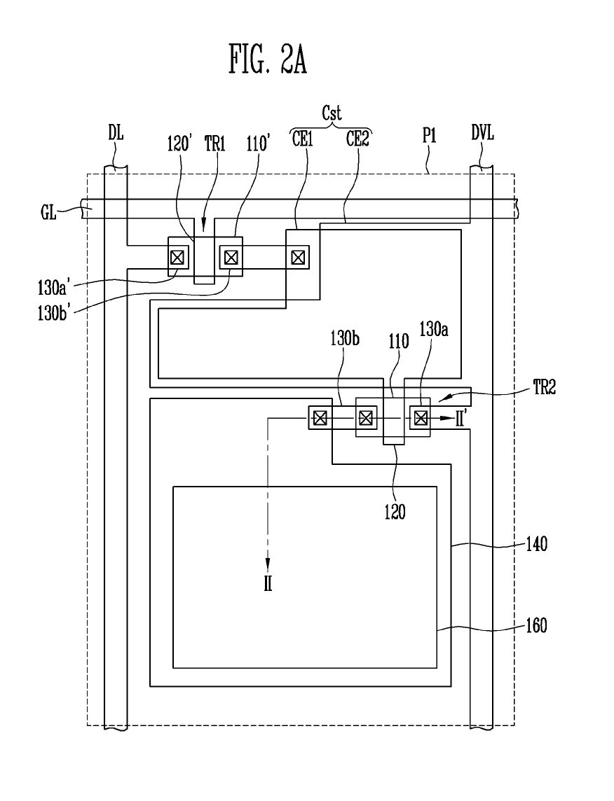

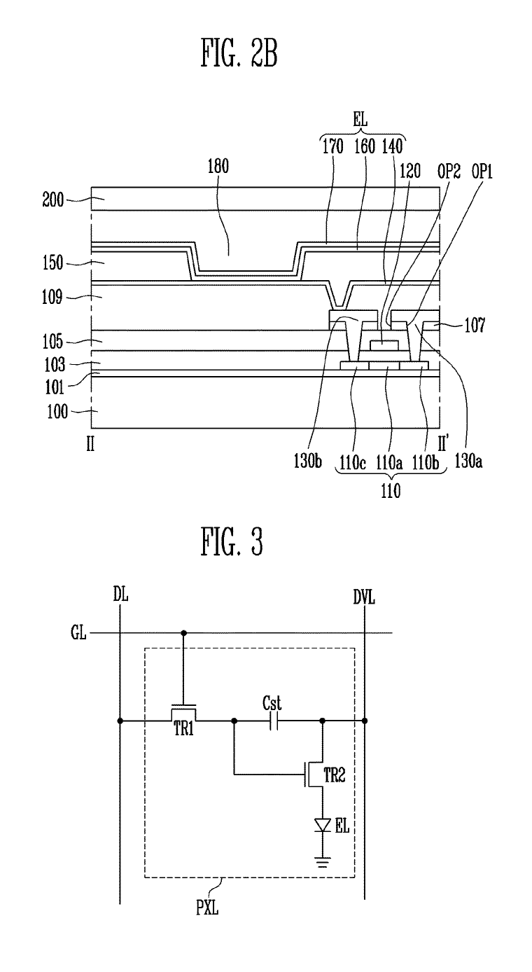

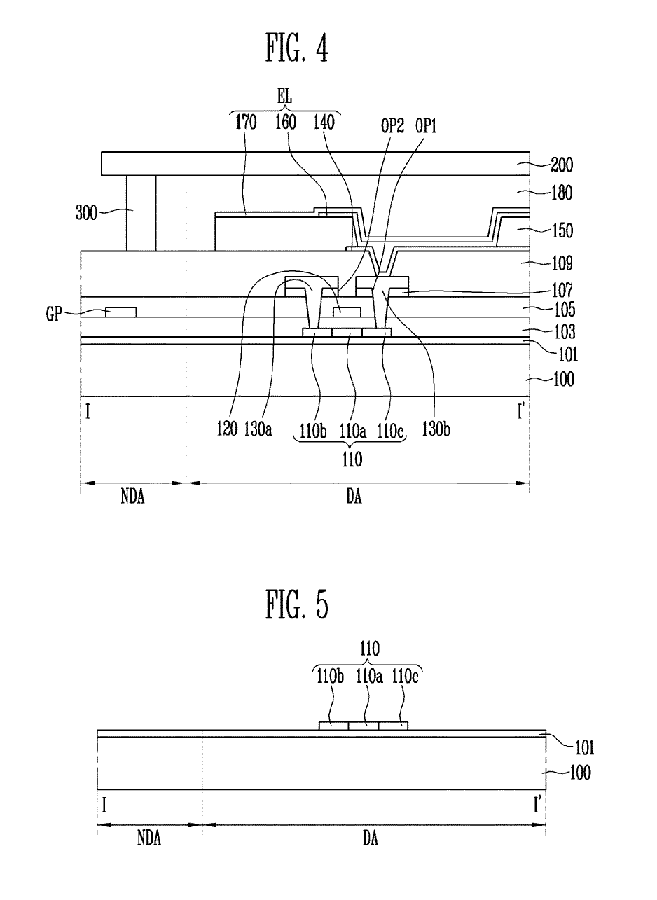

FIG. 1 is a schematic top plan view of an organic light emitting (OLED) display according to an embodiment of the present invention, FIG. 2A is a top plan view that enlarges P1 of FIG. 1, and FIG. 2B is a cross-sectional view along II-IF line of FIG. 2A, FIG. 3 is a circuit diagram of one pixel in an organic light emitting diode (OLED) display according to an embodiment of the present invention, and FIG. 4 is a cross-sectional view along I-I′ line of FIG. 1.

Hereinafter, referring to FIG. 1 to FIG. 4, an organic light emitting diode (OLED) display will be described according to an embodiment of the present invention. Merely, an active matrix type organic light emitting element using a top gate type driving transistor is instantiated, but is not limited thereto.

Referring to FIG. 1 to FIG. 4, an organic light emitting diode (OLED) display according to an embodiment of the present invention includes a first substrate 100 having a quadrangle shape and a second substrate 200 facing the first substrate 100. The first substrate 100 and the second substrate 200 may have a rectangular shape having a pair of lone sides and a pair of short sides. Here, the second substrate 200 may be smaller than the first substrate 100, and thus a part of the first substrate 100 can be exposed.

The first substrate 100 can be one of a film substrate and a plastic substrate including high molecule organic material having flexibility. The second substrate 200 is a encapsulating member that covers the first substrate 100, is formed by transparent material in case of a front side luminescence or both sides luminescence, and may be formed by opaque material in case of a rear side luminescence.

A sealing material 300 having a rectangle shape of a closed loop is formed to prevent the inflow of moisture and oxygen from the outside and surround a display area (DA) of the first substrate 100.

In an embodiment of the present invention, it is described that a substrate that is provided with a thin film transistor is a first substrate 100 and a substrate that faces the first substrate 100 is a second substrate 200, this is only for a better understanding and an ease of description, and the name and the position of the substrates may be changed. For example, the first substrate 100 and the second substrate 200 may be referred to respectively a lower substrate and an upper substrate.

The first substrate 100 is provided with a plurality of pixel (PXL) and includes a display area (DA) displaying images and at least one side of the display area (DA) e.g. non-display area (NDA) surrounding the display area (DA).

The pixels (PXL) may be arranged by matrix format. The pixel (PXL) may display variety of colors and it is instantiated that each pixel emits a specific color, e.g. red color light, green color light, and blue color light in an embodiment of the present invention.

Here, it is described that the pixel (PXL) has a rectangular shape, but it is not limited thereto and the shape of the pixel may be variously changed. Also, the pixels (PXL) may have different areas from each other.

The pixel (PXL) includes a wire portion, a thin film transistor connected to the wire portion, an organic light emitting element (EL) connected to the thin film transistor, and a capacitor (Cst).

The wire portion includes a plurality of gate lines (GL), a plurality of data lines (DL), a driving voltage line (DVL), and the gate lines (GL) and the data lines (DL) can be connected to an outside wire through gate pads (GP) and data pads (DP) that is respectively formed on the non-display area (NDA).

The gate line (GL) is extended to a first direction D1. The data line (DL) is extended to a second direction D2 that intersects with the first direction D1. The driving voltage line (DVL) is extended to a direction substantially equivalent to the data line (DL). The gate line (GL) transmits a scan signal to the thin film transistor, the data line (DL) transmits a data signal to the thin film transistor, and the driving voltage line (DVL) transmits a driving voltage to the thin film transistor.

The thin film transistor may include a driving thin film transistor TR2 for controlling the organic light emitting element (EL) and a switching thin film transistor TR1 for switching the driving thin film transistor TR2. In an embodiment of the present invention, it is described that one pixel (PXL) includes two thin film transistor TR1 and TR2, but it is not limited thereto, one thin film transistor and one capacitor may be prepared for one pixel (PXL) or at least three thin film transistor and at least two capacitors may be prepared for one pixel (PXL).

The switching thin film transistor TR1 includes a first semiconductor layer portion or piece 110′, a first gate electrode 120′, a first source electrode 130a′, and a first drain electrode 130b′. The first gate electrode 120′ is connected to the gate line (GL), and the first source electrode 130a′ is connected to the data line (DL). The drain electrode 130b′ is connected to the second gate electrode 120 of the driving thin film transistor TR2. The switching thin film transistor TR1 transmits the data signal that is transmitted to the data line (DL) to the driving thin film transistor TR2 in accordance with the scan signal that is transmitted to the gate line (GL).

The driving thin film transistor TR2 includes a second semiconductor layer portion 110, a second gate electrode 120, a second source electrode 130a, and second drain electrode 130b. The second gate electrode 120 is connected to the switching thin film transistor TR1, the second source electrode 130a is connected to the driving voltage line (DVL), and the second drain electrode 130b is connected to the organic light emitting element (EL).

The organic light emitting element (EL) includes a first electrode 140, an organic emission layer 160 on the first electrode 140, and a second electrode 170 on the organic emission layer 160.

The first electrode 140 is connected to a second drain electrode 130b of the driving thin film transistor TR2.

The capacitor Cst includes a first capacitor electrode CE1 that is connected to a drain electrode 130b of the switching thin film transistor TR1 and a second capacitor that is disposed on the first capacitor electrode CE1. The capacitor Cst is connected between the second source electrode 130a and the second gate electrode 120 of a driving thin film transistor TR2 and charges and maintains the data signal that is input to the second gate electrode 120 of the driving thin film transistor TR2.

Common voltage is applied to the second electrode 170, and the organic emission layer 160 emits light in accordance with the output signal of the driving thin film transistor TR2 to display images.

Hereinafter, an organic light emitting diode (OLED) display according to an embodiment of the present invention will be described depending on the laminated order.

An organic light emitting diode (OLED) display according to an embodiment of the present invention includes a first substrate 100 that a thin film transistor and an organic light emitting element are laminated.

A buffer layer 101 is formed on the first substrate 100. The buffer layer 101 prevents the impurity from being spread over the switching thin film transistor TR1 and the driving thin film transistor TR2. The buffer layer 101 may be made of silicon nitride (SiNx), silicon oxide (SiOx), silicon oxynitride (SiOxNy), and so on, and it may be omitted depending on the material of the first substrate 100 and process condition.

A first semiconductor layer portion 110′ and a second semiconductor layer portion 110 are provided on the buffer layer 101. The first semiconductor layer portion 110′ and the second semiconductor layer portion 110 are made of semiconductor material, and each of them is operated by an active layer of a switching thin film transistor TR1 and a driving thin film transistor TR2. The first semiconductor layer portion 110′ and the second semiconductor layer portion 110 respectively includes a channel region 110a between a source region 110b and a drain region 110c, and a source region 110b and drain region 110c. The first semiconductor layer portion 110′ and the second semiconductor layer portion 110 are respectively selected from an inorganic semiconductor or organic semiconductor. The source region 110b and the drain region 110c are doped by n-type impurity or p-type impurity.

A first insulation layer 103 is formed on the first semiconductor layer portion 110′ and the second semiconductor layer portion 110.

A first gate electrode 120′ and a second gate electrode 120 that are connected to a gate line (GL) are formed on the first insulation layer 103. The first gate electrode 120′ and the second gate electrode 120 is formed to cover an area that corresponds to a channel region 110a of the first semiconductor layer portion 110′ and the second semiconductor layer portion 110.

A second insulation layer 105 is formed on the first gate electrode 120′ and the second gate electrode 120 to cover the first gate electrode 120′ and the second gate electrode 120.

A first source electrode 130a′, a first drain electrode 130b′, a second source electrode 130a, a second drain electrode 130b, a data line (DL), and a driving voltage line (DVL) are formed on the second insulation layer 105.

The first source electrode 130a′ and the first drain electrode 130b′ respectively contact a source region 110b and a drain region 110c of the first semiconductor layer portion 110′ through an opening that is formed on the first insulation layer 103 and the second insulation layer 105. The second source electrode 130a and the second drain electrode 130b respectively contact a source region 110b and a drain region 110c of the second semiconductor layer portion 110 through an opening that is formed on the first insulation layer 103 and the second insulation layer 105.

A third insulation layer 109 is formed on the first source electrode 130a′, the first drain electrode 130b′, the second source electrode 130a, the second drain electrode 130b, the data line (DL), and the driving voltage line (DVL).

Here, the first source electrode 130a′ and the first drain electrode 130b′ are separated from each other. The second source electrode 130a and the second drain electrode 130b are also separated from each other.

The third insulation layer 109 covers the switching thin film transistor TR1 and the driving thin film transistor TR2, and may include at least one film. Specifically, the third insulation layer 109 may include organic insulating material that is transparent and has flexibility to mitigate and flatten the flexion of a lower structure. The organic insulating material may include polyimide.

A first electrode 140 of organic light emitting element (EL) is formed on the third insulation layer 109. The first electrode 140 is connected to a second drain electrode 130b of the driving thin film transistor TR2 through a contact hole that is formed in the third insulation layer 109.

A pixel defining layer 150 is formed on the first substrate 100, in which the first electrode 140 is formed, to divide an area that an organic emission layer 160 is to be formed. The pixel defining layer 150 exposes an upper surface of the first electrode 140 and protrudes from the first substrate 100 along a circumference of each pixel (PXL).

An organic emission layer 160 is provided on an area that is surrounded by the pixel defining layer 150 to emit a specific color of light. A second electrode 170 is provided on the organic emission layer 160. A filling material 180 is provided on the second electrode 170 to cover the second electrode 170.

Here, the organic emission layer 160 includes organic light emitting material that emits red, green, and blue color light, or emits white color light. In the drawing, it is shown that the organic emission layer 160 has one layer, but it is not limited thereto, the organic emission layer 160 may have a multilayer structure. For example, the organic emission layer 160 may be provided with an electron injection layer (EIL), an electron transport layer (ETL), a hole injection layer (HIL), a hole transport layer (HTL), and so on.

Meanwhile, insulation material pieces 107 are further formed on the second insulation layer 105. The insulation material pieces 107 respectively corresponds to a lower portion of the first source electrode 130a′, a lower portion of the first drain electrode 130b′, a lower portion of the second source electrode 130a, a lower portion of the second drain electrode 130b, a lower portion of the data line (DL), and a lower portion of the driving voltage line (DVL). Each insulation material piece 107 is patterned to have a first opening OP1 that corresponds to an opening that is formed on the first insulation layer 103 and the second insulation layer 105.

An insulation material piece 107 that is disposed at a lower portion of the first source electrode 130a′ has a side that coincides with a side of the first source electrode 130a′. Also, an insulation material piece 107 that is disposed at a lower portion of the second source electrode 130a has a side that coincides with a side of the second source electrode 130a.

An insulation material piece 107 that is disposed at lower portion of the first drain electrode 130b′ has a side that coincides with a side of the first drain electrode 130b′. Also, an insulation material piece 107 that is disposed at a lower portion of the second drain electrode 130b has a side that coincides with a side of the second drain electrode 130a.

The insulation material pieces 107 may be provided with organic insulating material including photosensitive and thermosetting material so as to improve flexibility. A weight loss of the organic insulating material is smaller than about 0.5% at a temperature below about 400° C. As organic insulating material that the weight loss is smaller than about 0.5% at a temperature under about 400° C., there are acryl-based polymer, imide-based polymer, aryl ether-based, amide-based polymer, Siloxane, and so on. Also, the organic insulating material may have dielectric constant (k) of more than 3.

Each insulation material piece 107 is formed at a specific area or location of a display area (DA) of the first substrate 100. The specific area includes a lower portion of the data line (DL), a lower portion of the driving voltage line (DVL), a lower portion of the first and second source electrode (130a′, 130a), and a lower portion of the first and second drain electrode (130b′, 130b).

Because the insulation material piece 107 that is made of organic insulating material is formed on a specific area of a display area (DA) of the first substrate 100, an area of the insulation material piece 107 is reduced in the display area (DA). Accordingly, an out-gassing of the insulation material piece 107 that is made of organic insulating material is reduced and the degradation of the organic light emitting element (EL) may be prevented thereby.

Although, the insulation material piece 107 that is made of organic insulating material is formed only a specific area of the display area (DA), the third insulation layer 109 made of polyimide is formed on a front side of the first substrate 100 such that the flexibility of the organic light emitting diode (OLED) may be improved.

In the drawing, it shows that the insulation material piece 107 is not formed on non-display area (NDA) of the first substrate 100, but the insulation material piece 107 may be formed on non-display area (NDA) of the first substrate 100.

In a case that the insulation material piece 107 is formed on the non-display area (NDA), an insulation material piece 107 of the display area (DA) and an insulation material piece 107 of the non-display area (NDA) are separated from each other such that out-gassing of the insulation material piece 107 of the non-display area (NDA) does not flow into the display area (DA). Hereinafter, a manufacturing method for an organic light emitting diode (OLED) display according to an embodiment of the present invention will be described.

FIG. 5 to FIG. 15 are cross-sectional views showing a manufacturing method of an organic light emitting diode (OLED) display along an embodiment of the present invention.

Referring to FIG. 5, a buffer layer 101 is formed on a first substrate 100, and a semiconductor layer portion 110 is formed at one area of the buffer layer 101. Here, the first substrate 100 may be divided into a display area (DA) and a non-display area (NDA) surrounding an outside of the display area (DA).

Material for forming elements in the first substrate 100 may be selected from material that a mechanical strength and a dimensional safety thereof are excellent. As material of the first substrate 100, there are a glass plate, a metal plate, a ceramic plate, or a plastic (poly carbonate resin, acryl resin, vinyl chloride resin, polyethylene terephthalate resin, polyimide resin, polyether resin, epoxy resin, silicon resin, fluorine resin, and so on, but it is desirable that it is made of plastic.

The buffer layer 101 is formed to protect driving elements that is formed in a later process from impurities like alkali ion that is released from the first substrate 100. The buffer layer 101 is made of silicon nitride (SiNx), silicon oxide (SiOx), silicon oxynitride (SiOxNy), and may be omitted depending on the material of the first substrate 100.

The semiconductor layer portion 110 is formed in a display area (DA) of the first substrate 100 on the buffer layer 101 and includes a channel region 110a that impurity is not injected, and a source region 110b and a drain region 110c that impurity of n-type or p-type is injected.

Referring to FIG. 6, a first insulation layer 103 is formed on the semiconductor layer portion 110 and the buffer layer 101. Subsequently, a gate electrode 120 and a gate pad portion (GP) are formed on the first insulation layer 103.

The first insulation layer 103 is formed on the semiconductor layer portion 110 and includes an opening that respectively exposes a part of the source region 110b and the drain region 110c. The first insulation layer 103 may include inorganic insulating material. The first insulation layer 103 may be a single layer that is selected from silicon nitride (SiNx), silicon oxide (SiOx), silicon oxynitride (SiOxNy) or may include a laminated layer structure having at least two sub-layers, each of which is formed of one selected from silicon nitride (SiNx), silicon oxide (SiOx), silicon oxynitride (SiOxNy).

The gate electrode 120 is formed in an area that corresponds to the channel region 110a that is formed in a display area (DA) of the first substrate 100 on the first insulation layer 103. The gate pad portion (GP) is formed in a non-display area (NDA) of the first substrate 100 on the first insulation layer 103.

The gate electrode 120 and the gate pad portion (GP), for example, may be made of a single kind or various kinds of metal, or alloy of them. Specifically, the gate electrode 120 and the gate pad portion (GP) may be formed as one layer that is selected from molybdenum (Mo), tungsten (W), aluminum neodymium (AlNd), titanium (Ti), aluminum (Al), silver (Ag), alloy of them, and the mixture of them or may be formed as two layer or multi layer of molybdenum (Mo), aluminum (Al) or silver (Ag) that are low resistance material so as to reduce wire resistance.

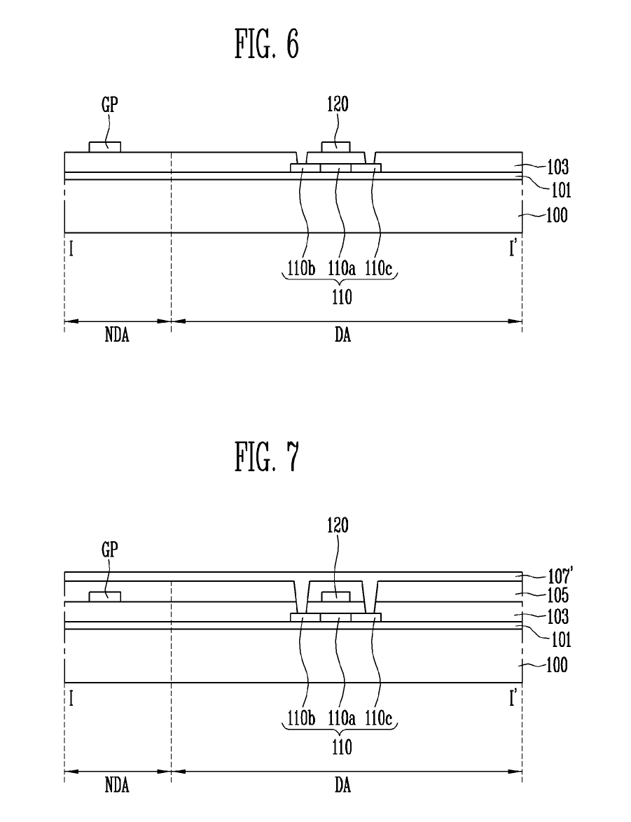

Referring to FIG. 7, a second insulation layer 105 is formed on the gate electrode 120 and the gate pad portion (GP). Subsequently, an organic insulating material layer 107′ is formed on the second insulation layer 105.

The second insulation layer 105 is made of one insulating material selected from inorganic insulating material or organic insulating material, is formed on the gate electrode 120, the gate pad portion (GP), and the first insulation layer 103 and includes an opening that exposes a part of the source region 110b and the drain region 110c.

The organic insulating material layer 107′ includes a photosensitive and thermosetting material that improves flexibility. A weight loss of the organic insulating material layer 107′ is smaller than about 0.5% at a temperature below about 400° C. Photosensitive and thermosetting material that the weight loss thereof is smaller than about 0.5% at a temperature below about 400° C. may be acryl-based polymer, imide-based polymer, aryl-ether based polymer, amide based polymer, siloxane, and so on.

Referring to FIG. 8, the organic insulating material layer 107′ is patterned to form organic insulating material pattern 107″ including first openings OP1 that exposing a part of the source region 110b and a part of the drain region 110c, respectively through a process like photolithography. Each first opening OP1 corresponds to an opening that is formed in the first insulation layer 103 and the second insulation layer 105.

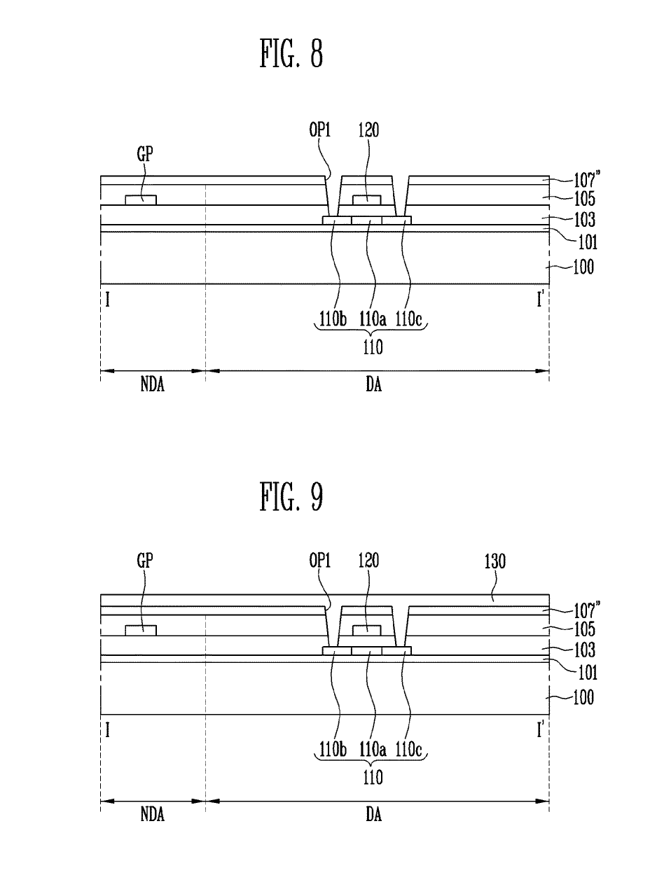

Referring to FIG. 9, a conductive layer 130 is formed on the organic insulating material pattern 107″ including the first openings OP1. The conduction layer 130 may be made of single metal, but it may be made of at least two kinds of metal or alloy of at least two kinds metal. Specifically, the conductive layer 130 may be formed as one layer that is selected from molybdenum (Mo), tungsten (W), aluminum neodymium (AlNd), titanium (Ti), aluminum (Al), silver (Ag), alloy of them, and the mixture of them or may be formed as two layer or multi layer of molybdenum (Mo), aluminum (Al) or silver (Ag) that are low resistance material so as to reduce wire resistance.

Referring to FIG. 10, the conductive layer 130 is patterned by a process like photolithography to form a source electrode 130a that contacts the source region 110b and a drain electrode 130b that contacts the drain region 110c. Here, the source electrode 130a and the drain electrode 130b separated from each other by a predetermined distance.

At least a portion of the insulation material pattern 107″ on which the source electrode 130a and the drain electrode 130b are not formed is exposed to the outside.

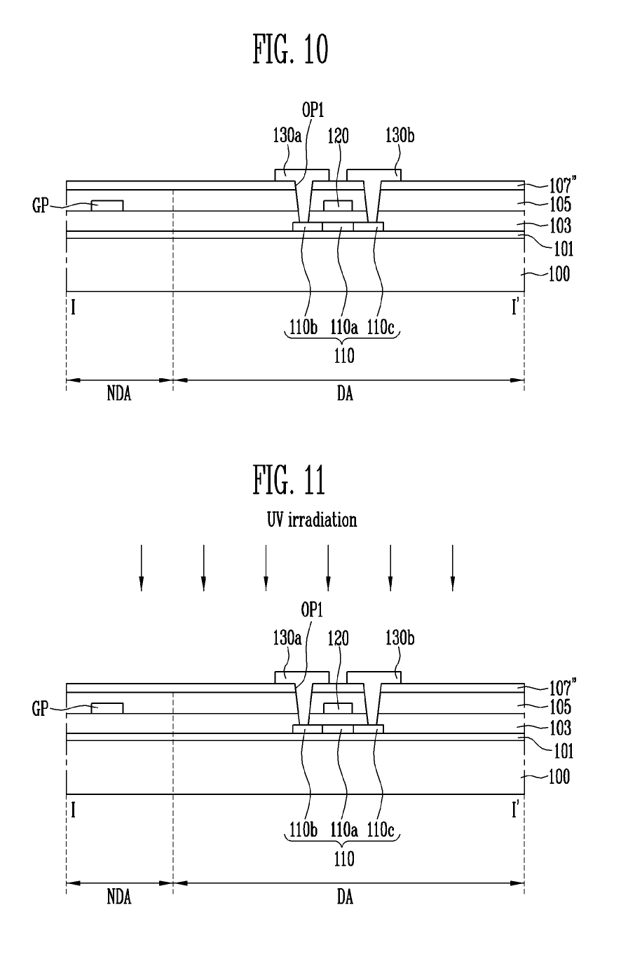

Referring to FIG. 11, the source electrode 130a and the drain electrode 130b function as a mask, UV is applied to a front side the first substrate 100 to eliminate the organic insulating material pattern 107″ that is exposed to the outside.

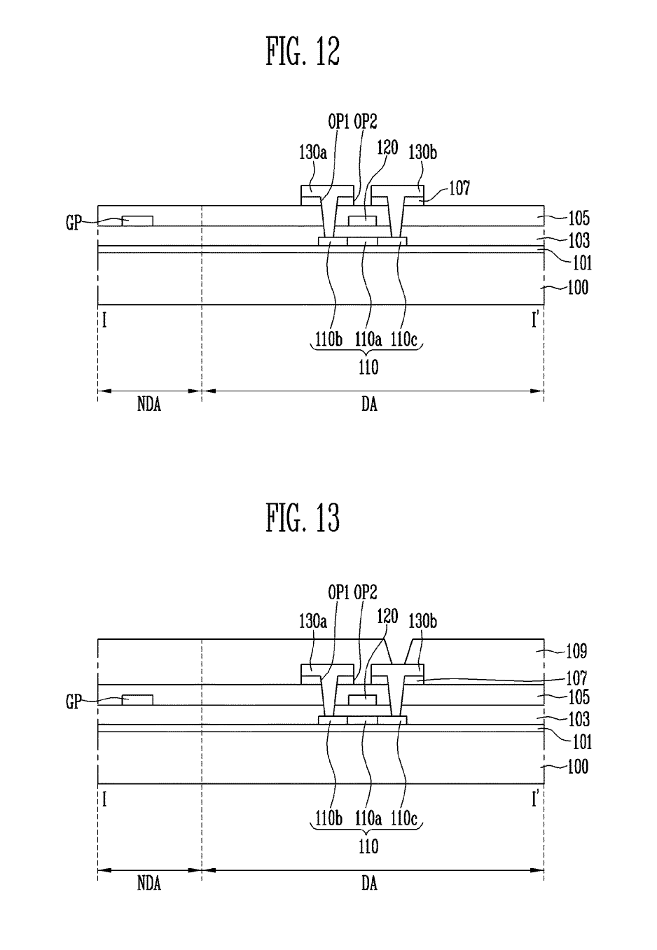

Referring to FIG. 12, insulation material pieces 107 are formed on the second insulation layer to be respectively disposed at a lower portion of the source electrode 130a and at a lower portion of the drain electrode 130b. Here, a second opening OP2 is formed between the source electrode 130a and the drain electrode 130b to expose a part of the second insulation layer 105. In the illustrated embodiments, the insulation material pieces 107 are separated from each other. However, embodiments of the invention are not limited thereto. In alternative embodiments, the insulation material pieces are connected to each other.

The insulation material piece 107 that is disposed at a lower portion of the source electrode 130a includes the first opening OP1, and has a side that coincides with a side of the source electrode 130a. Also, the insulation material piece 107 that is disposed at a lower portion of the drain electrode 130b includes the first opening OP1, and has a side that coincides with a side the drain electrode 130b.

The insulation material piece 107 may be provided with organic insulating material including photosensitive and thermosetting material so as to improve flexibility. A weight loss of the organic insulating material is smaller than about 0.5% at a temperature below about 400° C. The organic insulating material that the weight loss thereof is smaller than about 0.5% at a temperature below about 400° C. may be acryl-based polymer, imide-based polymer, aryl-ether based polymer, amide-based polymer, siloxane, and so on. Also, the organic insulating material may have a dielectric constant (k) of more than 3.0.

Referring to FIG. 13, a third insulation layer 109 as an insulating material is formed on the first substrate 100 that the second opening OP2, the insulation material piece 107, the source electrode 130a, and the drain electrode 130b. A contact hole is formed on the third insulation layer 109 by using a photolithography process so as to expose a part of the drain electrode 130b.

Here, the third insulation layer 109 may be formed by an organic insulating material that is transparent, has fluidity to soften a flexion of a lower structure, and evens the surface. The organic insulating material may be polyimide.

Because the third insulation layer 109 is formed by organic insulating material such as polyimide and on a front side of the first substrate 100, the flexibility thereof may be further improved.

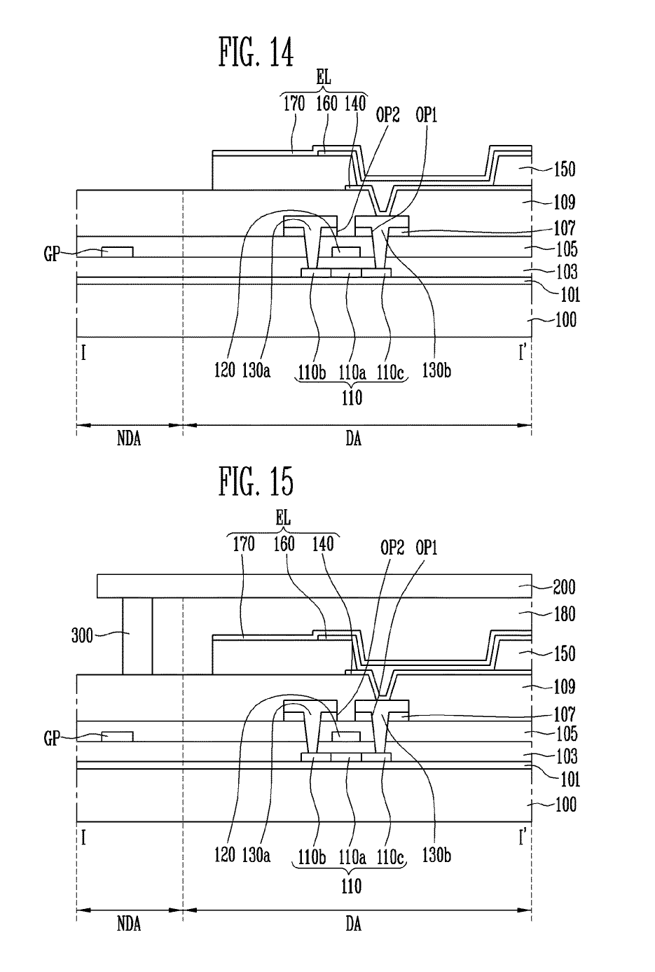

Referring to FIG. 14, an organic light emitting element (EL) is formed on the first substrate 100 that the third insulation layer 109 is formed. The organic light emitting element (EL) includes a first electrode 140 connected to the drain electrode 130b, an organic emission layer 160 that is formed on the first electrode 140, and a second electrode 170 that is disposed on the organic emission layer 160.

The organic light emitting element (EL) is formed as follows.

First, transparent conductivity oxide layer is formed on the third insulation layer 109, and the transparent conductivity oxide layer is patterned to form the first electrode 140. The first electrode 140 is joined with the drain electrode 130b. After forming the first electrode 140, a pixel defining layer 150 is formed to expose a part of the first electrode 140 on the first electrode 140. The pixel defining layer 150 is formed by organic insulating material to cover the first electrode 140 and is formed by patterning the organic insulating material. After forming the pixel defining layer 150, an organic emission layer 160 is formed on the first electrode 140 that is exposed by the pixel defining layer 150. The organic emission layer 160 includes an emission layer and generally may have a multi-layered thin layer structure. After forming the organic emission layer 160, the second electrode 170 is formed on the organic emission layer 160.

Referring to FIG. 15, after forming the organic light emitting element (EL), a second substrate 200 is formed to isolate the organic light emitting element (EL) from the outside. In addition, a filling material 180 is filled between the first substrate 100 and the second substrate 200.

Continuously, a sealant 300 is disposed on the edge of the first substrate 100 to seal the first substrate 100 and the second substrate 200.

An organic light emitting diode (OLED) display having the above configuration according to an embodiment of the present invention uses data wire as a mask and form an insulation material piece 107 only on a specific area of a display area (DA) such that the area of the insulation material piece 107 may be reduced in the display area (DA). As a result, an out-gassing phenomenon of the insulation material piece 107 is minimized to prevent the degradation of the organic light emitting element (EL).

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting diode (OLED) display, comprising:
a substrate;
a semiconductor layer portion disposed over the substrate and comprising an active region, a source region, and a drain region;
a first insulation layer disposed over the substrate and covering the semiconductor layer portion;
a gate electrode disposed over the first insulation layer and overlapping the active region, the first insulation layer interposed between the gate electrode and the semiconductor layer portion;
a second insulation layer disposed over the first insulation layer and covering the gate electrode;
a first insulation material piece disposed over the second insulation layer;
a source electrode disposed over the first insulation material piece and connected the source region through a contact via formed through the first and second insulation layers and the first insulation material piece;
a second insulation material piece disposed over the second insulation layer;
a drain electrode disposed over the second insulation material piece and connected to the drain region through another contact via formed through the first and second insulation layers and the second insulation material piece;
a third insulation layer disposed over the second insulation layer and covering the source electrode and the drain electrode;
a first electrode disposed over the third insulation layer and connected to the drain electrode through a contact hole formed through the third insulation layer;
an organic light emission layer disposed over the first electrode; and
a second electrode disposed over the organic light emission layer.

2. The organic light emitting diode (OLED) display of claim 1, wherein the first insulation material piece is disposed between the source electrode and the second insulation layer.

3. The organic light emitting diode (OLED) display of claim 2, wherein, when viewed in a viewing direction perpendicular to a major surface of the substrate, the first insulation material piece and the source electrode eclipse with each other such that the first insulation material piece does not comprises a substantial portion that does not overlap the source electrode.

4. The organic light emitting diode (OLED) display of claim 1, wherein the second insulation material piece is disposed between the drain electrode and the second insulation layer, wherein, when viewed in a viewing direction perpendicular to a major surface of the substrate, the second insulation material piece and the drain electrode eclipse with each other such that the second insulation material piece does not comprises a substantial portion that does not overlap the drain electrode.

5. The organic light emitting diode (OLED) display of claim 1, wherein the first insulation material piece is formed of an organic insulation material that comprises photosensitive and thermosetting material.

6. The organic light emitting diode (OLED) display of claim 5, wherein the organic insulation material comprises at least one selected from acryl-based polymer, imide-based polymer, aryl-ether based polymer, amide based polymer and siloxane.

7. The organic light emitting diode (OLED) display of claim 6, wherein a weight-loss of the organic insulating material is smaller than about 0.5% at a temperature below about 400° C.

8. The organic light emitting diode (OLED) display of claim 1, wherein the third insulation layer comprises polyimide.

9. The organic light emitting diode (OLED) display of claim 1, wherein the organic light emitting diode display comprises an array of pixels, each of which comprises the semiconductor layer portion, the first insulation layer, the gate electrode, the second insulation layer, the first insulation material piece, the source electrode, the second insulation material piece, the drain electrode, the third insulation layer, the first electrode, the organic light emitting layer and the second electrode.

10. A method of manufacturing an organic light emitting diode (OLED) display, comprising:
forming a semiconductor layer portion comprising an active region, a source region, and a drain region over a substrate;
forming a first insulation layer over the semiconductor layer portion;
forming a gate electrode over the first insulation layer and overlapping the active region;
forming a second insulation layer over the gate electrode;
forming an extra insulation layer over the second insulation layer;
forming a source electrode and a drain electrode over the extra insulation layer, wherein the source electrode is connected to the source region via a contact hole formed through the first and second insulation layers and the extra insulation layer, wherein the drain electrode is connected to the drain region via a contact hole formed through the first and second insulation layers and the extra insulation layer;
etching at least a portion of the extra insulation layer that is exposed outside the source and drain electrodes by using the source electrode and the drain electrode as an etching mask, thereby forming first and second insulation material pieces;
forming a third insulation layer over the source electrode and the drain electrode;
forming a first electrode over the third insulation layer, wherein the first electrode is connected to the drain electrode through a contact hole;
forming an organic emission layer over the first electrode; and
forming a second electrode over the organic emission layer.

11. The method of claim 10, wherein etching comprises irradiating ultraviolet (UV) light.

12. The method of claim 10, wherein the first insulation piece is disposed between the source electrode and the second insulation layer, and the second insulation material piece is disposed between the drain electrode and the second insulation layer.

13. The method of claim 12, wherein, when viewed in a viewing direction perpendicular to a major surface of the substrate, the first insulation material piece and the source electrode eclipse with each other such that the first insulation material piece does not comprises a substantial portion that does not overlap the source electrode.

14. The method of claim 12, wherein, when viewed in a viewing direction perpendicular to a major surface of the substrate, the second insulation material piece and the drain electrode eclipse with each other such that the second insulation material piece does not comprises a substantial portion that does not overlap the source electrode.

15. The method of claim 10, wherein the first and second insulation material pieces comprise organic insulating material that comprises photosensitive and thermosetting material.

16. The method of claim 15, wherein the organic insulating material comprises at least one that is selected from acryl-based polymer, imide-based polymer, aryl-ether based polymer, amide-based polymer, and siloxane.

17. The method of claim 16, wherein a weight-loss of the organic insulating material is smaller than about 0.5% at a temperature below about 400° C.

18. The method of claim 10, wherein the third insulation layer comprises polyimide.

19. The method of claim 10, further comprising:
forming at least one electrically conductive material line over the extra insulation layer; and
etching at least a portion of the extra insulation layer that is exposed outside the at least one electrically conductive material line by using the at least one electrically conductive material line as an etching mask, thereby forming at least one additional insulation material piece between the at least one electrically conductive material line and the second insulation layer.

20. The method of claim 10, wherein the organic light emitting diode display comprises an array of pixels, each of which comprises the semiconductor layer portion, the first insulation layer, the gate electrode, the second insulation layer, the first insulation material piece, the source electrode, the second insulation material piece, the drain electrode, the third insulation layer, the first electrode, the organic light emitting layer and the second electrode.
